(19) United States
(12) Patent Application Publication
(10) Pub. No.: US 2018/0130912 A1
(43) Pub. Date: May 10, 2018

(54) FIELD EFFECT TRANSISTOR INCLUDING GRAPHENE LAYER

(71) Applicants: SUMITOMO ELECTRIC INDUSTRIES, LTD., Osaka (JP); TOHOKU UNIVERSITY, Sendai-shi (JP)

(72) Inventors: Yasunori TATENO, Yokohama-shi (JP); Masaki UENO, ltami-shi (JP); Masaya OKADA, ltami-shi (JP); Fuminori MITSUHASHI, ltami-shi (JP); Maki SUEMITSU, Sendai-shi (JP); Hirokazu FUKlDOME, Sendai-shi (JP)

(73) Assignees: SUMITOMO ELECTRIC INDUSTRIES, LTD., Osaka (JP); TOHOKU UNIVERSITY, Sendai-shi (JP)

(21) Appl. No.: 15/804,677

(22) Filed: Nov. 6, 2017

(30) Foreign Application Priority Data
Nov. 7, 2016 (JP) 2016-217291

(51) Int. Cl. H01L 29/786; H01L 27/088; H01L 29/66; H01L 29/16; H01L 29/423; H01L 21/02; H01L 29/49; H01L 21/82

(52) U.S. Cl. CPC H01L 29/78696; H01L 27/088; H01L 29/78684; H01L 29/78645; H01L 29/78603; H01L 29/66045; H01L 29/165; H01L 29/423; H01L 21/02527; H01L 21/02614; H01L 29/4908; H01L 21/8213; H01L 29/42384; H01L 29/1606

(57) ABSTRACT

A field effect transistor (FET) including a graphene layer as a carrier transporting channel is disclosed. The FET provides, on a substrate, a graphene layer, and electrodes of the source and drain on the graphene layer. The FET further provides a couple of gate electrodes and a supplemental electrode, where the former two gate electrodes are provided on a gate insulating film, while, the latter one is provided on the graphene layer and between two gate electrodes. The second gate electrode provided closer to the drain electrode has a gate length that is shorter than the gate length of the first gate electrode provided closer to the source electrode.

### BACKGROUND OF INVENTION

### 1. Field of Invention

The present invention relates to a field effect transistor (PET), in particular, an FET including a graphene layer as a carrier transporting layer.

### 2. Related Background Art

A graphene is a sheet or a two-dimensional material made of carbons formed in six-membered ring, and shows extremely superior electron mobility. A transistor type of field effect transistor (FET) has been developed where a channel layer thereof is made of graphene. A dual gate FET with the channel layer made of graphene has been also known in the field.

The second gate electrode positioned closer to the drain electrode may suppress the hole injection from the drain electrode into the channel beneath the first gate electrode disposed closer to the source electrode, which may improve the drain conductance and enhance the performance of the FET such as the maximum frequency of oscillation fmax. However, because of graphene as a newly developed material, an FET with the channel layer made of graphene in performance thereof is not sufficient to be practically acceptable in the field.

### SUMMARY OF INVENTION

An aspect of the present invention relates to a field effect transistor (FET) that includes a substrate, a graphene layer, electrodes of a source and a drain, a gate insulating film, and first and second gate electrodes. The graphene layer is provided on the substrate and operates as a channel layer. The electrodes of the source and the drain are provided on the graphene layer. The gate insulating film covers the graphene layer exposed between the source and drain electrodes. The first and second gate electrodes are provided on the gate insulating film. Thus, the FET of the present invention is a type of metal-oxide semiconductor (MOS) FET, A feature of the FET of the present invention is that the second gate electrode disposed relatively closer to the drain electrode has a gate length shorter than a gate length of the first gate electrode disposed closer to the source electrode.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a cross section of a field effect transistor (FET) according to the first embodiment of the present invention

FIG. 2 shows an equivalent circuit diagram of the FET shown in FIG. 1;

FIG. 3 shows behaviors of the cut off frequency fT and the maximum frequency of oscillation of the FET shown in FIG. 1 against the summed distance of the gate length of the second gate electrode and the distance between two gate electrodes;

FIGS. 4A to 4C show cross sections of the FET shown in FIG. 1 at respective processes; and

FIGS. 5A to 5C show cross sections of the FET at respective processes subsequent to those shown in FIGS. 4A to 4C.

### DESCRIPTION OF EMBODIMENT

### First Embodiment

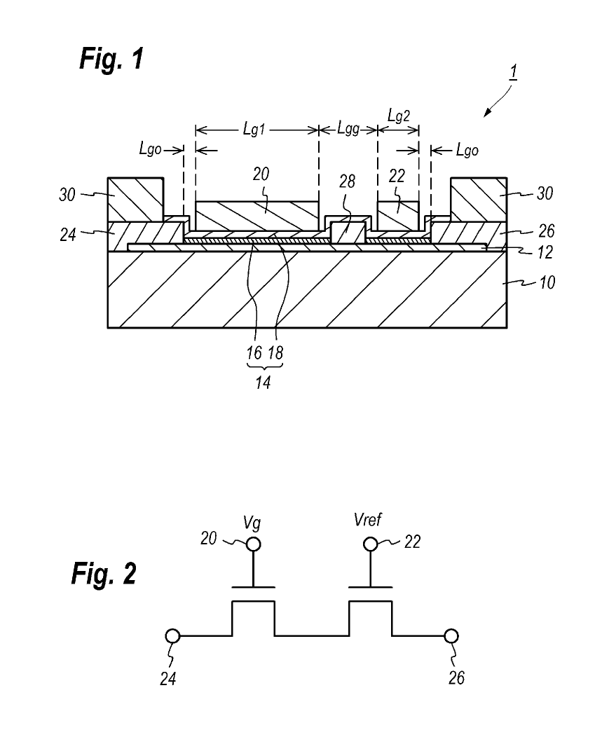

FIG. 1 shows a cross section of a field effect transistor (FET) according to the first embodiment of the present invention. The FET 1 shown in FIG. 1 provides a graphene layer 12 on a substrate 10, but the graphene layer 12 except for an active region is removed. The graphene layer 12 provides a source electrode 24 and a drain electrode 26 thereon. Also, the graphene layer 12 provides, between the source electrode 24 and the drain electrode 26, a first gate electrode 20 and a second gate electrode 22 as interposing a gate insulating film 14 therebetween. The gate insulating film 14 includes an aluminum oxide 16 and a silicon oxide 18. The first and second gate electrodes, 20 and 22, sandwiches an ohmic electrode 28. The source electrode 24 and the drain electrode 26 connect interconnections drawn from an inactive region where the graphene layer 12 is removed.

Denoting gate lengths of the first and second gate electrodes, 20 and 22, as Lg1 and Lg2, respectively, a distance between two gate electrodes, 20 and 22, as Lgg, and distances between the first gate electrode 20 and the source electrode 24 and between the second gate electrode 22 and the drain electrode 26 as Lgo; those lengths, Lg1, Lg2, Lgg, and Lgo are defined by lengths at interfaces between the respective electrodes and the graphene layer 12. The FET 1 according to the first embodiment provides the second gate 22 whose length Lg2 is shorter than the gate length Lg1 of the first gate electrode 20.

FIG. 2 shows an equivalent circuit diagram of the FET 1 shown in FIG. 1. The FET 1 provides, as shown in FIG. 2, two gate electrodes, 20 and 22, between the source electrode 24 and the drain electrode 26. The first gate electrode 20 receives a gate bias Vg, while, the second gate electrode 22 receives a reference bias Vref. The reference bias Vref may suppress or prevent holes from being injected in a region under the first gate electrode 20 from the drain electrode 26 by adequately adjusting a level thereof, which means that, even a high drain bias is applied to the drain electrode 26, an increase of the hole concentration in the channel may be effectively prevented, and a drain current enough saturates to reduce the drain conductance. Various performances of the FET 1 may be improved. The reference bias Vref is preferably higher than the gate bias Vg applied to the first gate 20 to suppress the hole injection into the channel. In an example, the second gate electrode 22 is preferably connected to the source electrode 24, that is, the reference bias Vref is preferably comparable to the source level.

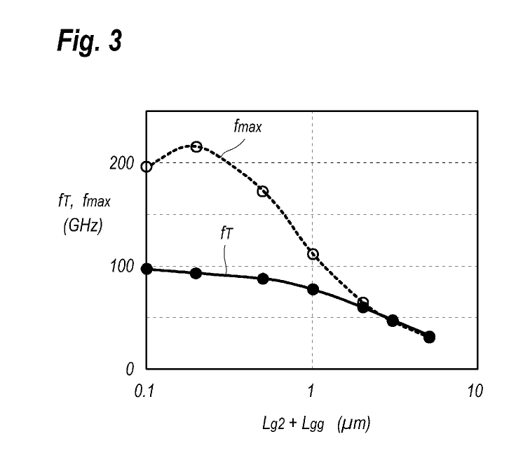

FIG. 3 shows behaviors of the cut off frequency fT and the maximum frequency of oscillation of the FET 1 against the summed distance of the gate length Lg2 of the second gate electrode 22 and the distance Lgg between two gate electrodes, 20 and 22, namely, Lg2+Lgg. As FIG. 3 shows, as the scammed distance Lg2+Lgg becomes smaller, the cut off frequency IT and the maximum frequency of oscillation fmax increases. In particular, the maximum frequency of oscillation fmax drastically increases when the summed distance Lg2+Lgg becomes shorter than the gate length Lg1 of the first gate electrode 20 because the drain access resistance caused by the channel between the first gate electrode 20 and the drain electrode 26 becomes small.

### Second Embodiment

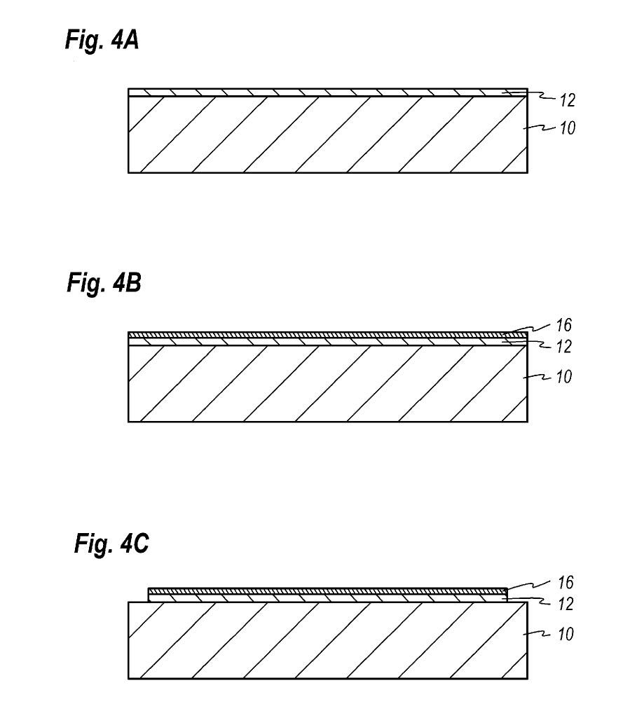

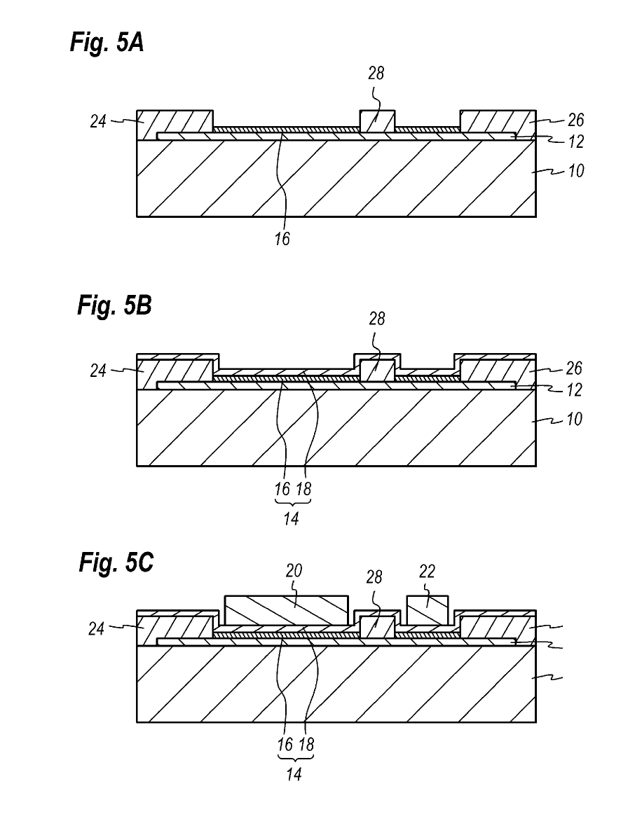

Next, a process of forming the FET 1 will be described according to the second embodiment of the present invention. FIGS. 4A to 5C show cross sections of the FET 1 at respective steps of the process of forming thereof. The process first prepares a substrate 10 made of silicon carbide (SiC) with the 6H polytypes by sequentially rinsing an SiC substrate within acetone for 5 minutes, ethanol for 5 minutes, and de-ionized water in 5 minutes. In an alternate, what is called, the RCA rinse sequentially using a mixture of sulfuric acid with hydrogen peroxide, fluoric acid, a mixture of ammonia with hydrogen peroxide, and a mixture of chloric acid with hydrogen peroxide. When the graphene layer 12 is formed by the thermal sublimation technique, the substrate 10 may be a silicon substrate with an SiC layer on a top most thereof. In an alternate, the graphene layer 12 may be formed by the chemical vapor deposition (CVD) technique. In such a case, the Si substrate is unnecessary to provide an SiC layer on the topmost surface thereof.

In the present embodiment, the thermal sublimation technique may form the graphene layer 12. Exposing the SiC substrate 10, or the Si substrate with the SiC layer on the topmost thereof, within an argon (Ar) atmosphere and heat-treating the substrate 10 at 1600° C. for one minute, the graphene layer 12 may be formed on the topmost of the substrate 10 by a thickness of 0.35 to 0.7 nm. The heat-treatment of the SiC substrate 10 may sublimate silicon (Si) atoms as leaving carbon (C) atoms bound with Sp2 hybridization on the topmost layer thereof. Conditions of an atmosphere, a treating temperature, and a treating time may control quality and a thickness of the graphene layer 12. Substantial vacuum atmosphere may be applicable to the heat treatment of the SiC substrate 10. An atmosphere by an inert gas may lower the growth rate of the graphene layer 12.

Then, a vacuum evaporation may form an aluminum (Al) film with a thickness of about 5 nm on the graphene layer 12, as indicated in FIG. 4B. In an alternate, a sputtering of aluminum (Al) may also form the Al film. After the deposition of the Al film, the Al film is oxidized by, for instance, exposing within an air for 24 hours. The air may naturally oxidize the Al film to form an aluminum oxide (Al₂O₃) 16 on the graphene layer 12. The atomic layer deposition (ALD) technique may also form the aluminum oxide (Al₂O₃) layer 16.

Then, the aluminum oxide (Al₂O₃) layer 16 and the graphene layer 12 in an inactive region surrounding the active region are removed by using a patterned photoresist. That is, the process first forms the patterned photoresist that covers the aluminum oxide (Al₂O₃) layer 16 and the graphene layer 12 only in the active region but exposes the aluminum oxide (Al₂O₃) layer in the inactive region. The aluminum oxide (Al₂O₃) layer in the inactive region may be etched by alkali developer, while, the graphene layer 12 may be etched by oxygen plasma, as indicated in FIG. 4C.

Openings are formed in the aluminum oxide (Al₂O₃) film left in the active region by the alkali developer using another patterned photoresist as an etching mask, where the openings are formed in regions corresponding to the source electrode 24, the drain electrode 26, and the supplemental electrode 28. Thereafter, an ohmic metal fills the openings as removing metals formed on the patterned photoresist by the lift-off technique, as shown in FIG. 5A. In the present embodiment, the ohmic metal may be made of nickel (Ni) with a thickness of about 15 nm.

Then, another insulating film 18 made of silicon oxide covers the aluminum oxide (Al₂O₃) layer between two gate electrodes, 20 and 22, and the source electrode 24, the drain electrode 26, and the supplemental electrode 28, as shown in FIG. 5B. The silicon oxide (SiO₂) film 18, which has a thickness of about 30 nm and is formed by, for instance, the CVD technique, may have a function to thicken the gate insulating film 14. That is, the silicon oxide (SiO₂) film 18 and the aluminum oxide (Al₂O₃) film may constitute the gate insulating film 14; but the gate insulating film 14 may be another material or other materials.

Thereafter, the process may form the first and second gate electrodes, 20 and 22, on the gate insulating film 14. The gate electrodes, 20 and 22, may be formed by stacked metals of titanium (Ti) with a thickness of 10 nm and gold (Au) with a thickness of 1000 nm. The vacuum evaporation accompanied with the lift-off technique may form the first and the second gate electrodes, 20 and 22. In an alternate, metal except for the combination above may be a gate electrode. From a viewpoint of reduction of gate resistance, metals with relatively lower resistance; or higher conductivity are preferable for the gate electrode. The present embodiment forms two gate electrodes, 20 and 22, at the same time. However, two gate electrodes, 20 and 22, may be formed independently and sequentially. From a viewpoint of the production, two gate electrodes, 20 and 22, are preferably formed concurrently.

Thereafter, another insulating film 18 made of silicon oxide (SiO₂) may cover the electrodes of the source 24, the drain, and the supplement 28, and the former silicon oxide (SiO₂) film 16. Forming vias in the lastly formed silicon oxide (SiO₂) film 18 in positions for the electrodes of the source 24, the drain 28, and two gate electrodes, 20 and 22, and forming interconnections 30 made of stacked metal of titanium (Ti) with a thickness of 10 nm and gold (Au) with a thickness of 100 nm so as to be in contact with the electrodes, 20 to 28, the process of forming the FET 1 shown in FIG. 1 is completed.

The embodiment thus described forms the electrodes of the source 24, the drain 26, and the supplement 28 in advance to the formation of two gate electrodes, 20 and 22. However, an alternate process may first form two gate electrodes, 20 and 22, then form the electrodes of the source 24, the drain 26, and the supplement 28.

The FET 1 according to the present invention provides two gate electrodes, 20 and 22, where the first one 20 is provided closer to the source electrode 24, while, the second one 22 is provided closer to the drain electrode 26, A feature of the FET 1 is that the second gate electrode 22 has the gate length. Lg2 is shorter than that Lg1 of the first gate electrode 20, which may reduce the resistance, exactly, the drain access resistance between the first gate electrode 20 and the drain electrode 26, thereby increasing the high frequency performance, such as the maximum frequency of oscillation fmax. The second gate electrode 22 in the gate length Lg2 thereof is preferably shorter than a half but longer than 1/10 of that Lg1 of the first gate electrode 20, or the second gate electrode 22 in the gate length Lg2 thereof is preferably longer than 0.1 μm. From the viewpoint of the manufacturing process of the FET 1, the gate length Lg2 of the second gate electrode 22 is preferably longer than 0.1 μm.

Also, the summed distance of the distance Lgg between two gate electrodes, 20 and 22, with the gate length Lg2 of the second gate electrode 22, namely, Lgg+Lg2, is preferably shorter than the gate length Lg1 of the first gate electrode 20; thereby the drain access resistance may be further reduced. The summed distance, Lgg+Lg2, is preferably shorter than a half but longer than ⅕ of the gate length Lg1 of the first gate electrode 20. In any gate length of the second gate electrode 22 and any distances Lgg between two gate electrodes, 20 and 22, the first gate electrode preferably has the gate length Lg1 thereof longer than 0.1 μm from the viewpoint of the process capability.

The FET 1 according to the present invention provides the supplemental electrode 28 between two gate electrodes, 20 and 22, where the supplemental electrode 28 is in contact with the graphene layer 12 and shows the un-rectified characteristic thereto. The supplemental electrode 28 may cover the surface of the graphene layer 12, which prevents the depletion layer formed under the gate insulating film 14 from widely expanding within the graphene layer 12 and also the resistance of the graphene layer 12 from being increased.

The second gate electrode 22 receives the reference signal Vref, which may suppress the hole injection from the drain electrode 26 into the graphene layer 12. The reference signal Vref is preferably greater than a bias supplied to the first gate electrode 20. The second gate electrode 22 is preferably short circuited with the source electrode 24.

The gate insulating film 14, which includes the aluminum oxide layer 16 and the silicon oxide layer 18, may isolate two gate electrodes, 20 and 22, from the graphene layer 12, that is, the FET 1 is operable as a type of metal-oxide-semiconductor (MOS) FET. Because of the dual insulating film of the aluminum oxide film 16 and the silicon oxide film 18 provided on the former oxide film 16, the gate insulating film may be formed thicker, which may enhance the reliability of the FET 1 but slightly degrades the gate conductance.

While particular embodiment of the present invention has been described herein for purposes of illustration, many modifications and changes will become apparent to those skilled in the art. Accordingly, the appended claims are intended to encompass all such modifications and changes as fall within the true spirit and scope of this invention.

The present application claims the benefit of priority of Japanese Patent Application No. 2016-217291, filed on Nov. 7, 2016, which is incorporated herein by reference.

What is claimed is:

1. A field effect transistor (FET), comprising;
a substrate;
a graphene layer provided on the substrate;
a source electrode and a drain electrode each provided on the graphene layer;
a gate insulating film provided on the graphene layer; and
a first gate electrode and a second gate electrode provided on the gate insulating film and between the source electrode and the drain electrode. the first gate electrode being closer to the source electrode, the second gate electrode being closer to the drain electrode,
wherein the second gate electrode has a gate length shorter than a gate length of the first gate electrode.

2. The FET according to claim 1,
wherein the gate length of the second gate electrode is shorter than a half of the gate length of the first gate electrode.

3. The FET according to claim 1,
wherein the first gate electrode and the second gate electrode form a distance therebetween, and
wherein the gate length of the second gate electrode summed with the distance between the first gate electrode and the second gate electrode is shorter than the gate length of the first gate electrode.

4. The FET according to claim 3,
wherein the gate length of the second gate electrode summed with the distance between the first gate electrode and the second gate electrode is shorter than a half of the gate length of the first gate electrode.

5. The FET according to claim 1,
further including a supplemental electrode that is in contact with the graphene layer and provided between the first gate electrode and the second gate electrode.

6. The FET according to claim 1,
wherein the second gate electrode is short-circuited with the source electrode.

7. The FET according to claim 1,
wherein the first gate electrode has a gate length shorter than 1 μm.

8. The FET according to claim 7,
wherein the gate length of the first gate electrode is longer than 0.1 μm.

9. The FET according to claim 1,
wherein the gate length of the second gate electrode is longer than 0.1 μm.
